(19) United States
(12) Patent Application Publication
(10) Pub. No.: US 2016/0260471 A1
(43) Pub. Date: Sep. 8, 2016

(54) SEMICONDUCTOR MEMORY DEVICE

(71) Applicant: Kabushiki Kaisha Toshiba, Tokyo (JP)

(72) Inventor: Osamu Hirabayashi, Tokyo (JP)

(21) Appl. No.: 14/852,177

(22) Filed: Sep. 11, 2015

(30) Foreign Application Priority Data
Mar. 6, 2015 (JP) 2015-045050

(51) Int. Cl. G11C 11/418; G11C 11/419

(52) U.S. Cl. CPC G11C 11/418; G11C 11/419

(57) ABSTRACT

According to one embodiment, a semiconductor memory device includes an SRAM. The SRAM comprises a memory cell including a first inverter, a second inverter, a first transfer transistor, and a second transfer transistor and a peripheral circuit configured to supply various voltages to a word line, a first bit line, and a second bit line. Each transistor of the memory cell is formed by a high-withstand-voltage transistor, and each transistor of the peripheral circuit is formed by a low-withstand-voltage transistor.

### CROSS-REFERENCE TO RELATED APPLICATIONS

This application is based upon and claims the benefit of priority from the prior Japanese Patent Application No. 2015-045050, filed Mar. 6, 2015, the entire contents of which are incorporated herein by reference.

### FIELD

Embodiments described herein relate generally to a semiconductor memory device.

### BACKGROUND

A backup SRAM (Static Random Access Memory) which backs up data (e.g., program data) in a semiconductor chip when the main power supply of the semiconductor chip is turned off has been proposed.

### BRIEF DESCRIPTION OF THE DRAWINGS

FIG. 1 is a block diagram showing a semiconductor memory device according to the first embodiment;

FIG. 2 is a block diagram showing the arrangement of an SRAM according to the first embodiment;

FIG. 3 is a circuit diagram showing the arrangement of a step-down circuit according to the first embodiment; and

FIG. 4 is a timing chart showing a retention operation and normal operation according to the first embodiment.

### DETAILED DESCRIPTION

In a retention operation (backup) in which the main power supply of a semiconductor chip is turned off, a backup SRAM (to be simply referred to as an SRAM hereinafter) temporarily holds (retains) data by using a voltage supplied from, e.g., a battery outside the chip. In accordance with the specifications of this battery, an external power supply which supplies a high voltage of 3.3 V is used.

By using this external power supply, a high voltage of 3.3 V can be applied to the SRAM in the retention operation or a normal operation. Therefore, high-withstand-voltage transistors (also called thick-film transistors) must be arranged all over the SRAM.

When using the high-withstand-voltage transistors, however, the spacing between N wells must be made wider than that when using low-withstand-voltage transistors, and the gate length of the transistors must be increased. This poses the problem that the circuit area of the SRAM increases.

Embodiments solve this problem by using low-withstand-voltage transistors (also called thin-film transistors) in peripheral circuits of the SRAM except for a memory cell array.

In general, according to one embodiment, a semiconductor memory device includes an SRAM. The SRAM includes a memory cell and a peripheral circuit. The memory cell includes a first inverter, a second inverter including an output terminal connected to an input terminal of the first inverter and an input terminal connected to an output terminal of the first inverter, a first transfer transistor including one terminal connected to the output terminal of the first inverter and the input terminal of the second inverter, the other terminal connected to a first bit line, and a gate connected to a word line, and a second transfer transistor including one terminal connected to the output terminal of the second inverter and the input terminal of the first inverter, the other terminal connected to a second bit line, and a gate connected to the word line. The peripheral circuit supplies various voltages to the word line, the first bit line, and the second bit line. Each transistor of the memory cell is formed by a high-withstand-voltage transistor, and each transistor of the peripheral circuit is formed by a low-withstand-voltage transistor having a withstand voltage lower than that of the high-withstand-voltage transistor.

Embodiments will be explained below with reference to the accompanying drawings. In these drawings, the same reference numerals denote the same parts. Also, a repetitive explanation will be made as needed.

### First Embodiment

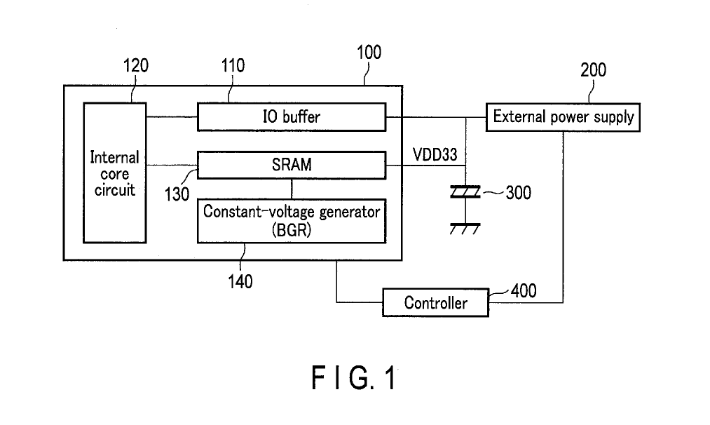

A semiconductor memory device according to the first embodiment will be explained with reference to FIGS. 1, 2, 3, and 4.

In an SRAM 130 of the first embodiment, high-withstand-voltage transistors are arranged in a memory cell array 131 to which a high voltage (e.g., 3.3 V) is applied as a maximum voltage from outside a chip. On the other hand, low-withstand-voltage transistors are arranged in peripheral circuits to which a low voltage (e.g., 1.2 V) is applied as a maximum voltage from an internal core circuit 120. This makes it possible to reduce the circuit area of the peripheral circuits, and reduce the circuit area of the whole SRAM. The first embodiment will be explained in detail below.

### [Arrangement of First Embodiment]

The arrangement of the semiconductor memory device according to the first embodiment will be explained below with reference to FIGS. 1, 2, and 3.

FIG. 1 is a block diagram showing the arrangement of the semiconductor memory device according to the first embodiment.

As shown in FIG. 1, this semiconductor memory device includes a semiconductor chip 100, external power supply 200, battery 300, and controller 400.

In the following explanation, a voltage VDD33 is a high voltage which is supplied from the external power supply 200 or battery 300, and for which a maximum voltage is about 3.3 V. Also, an internal core voltage VDDC is a low voltage which is supplied from an external power supply (not shown) other than the external power supply 200, and for which a maximum voltage is about 1.2 V. Furthermore, an external power terminal is a terminal to which the voltage VDD33 is supplied, and an internal core power terminal is a terminal to which the internal core voltage VDDC is supplied.

The external power supply 200 supplies a high voltage (e.g., 3.3 V) as the voltage VDD33 to the battery 300 or semiconductor chip 100. The battery 300 stores electric energy by using this high voltage from the external power supply 200. The battery 300 is used as a backup power supply when the main power supply (external power supply 200) is turned off (in a retention operation), and supplies a backup voltage (e.g., 2.0 to 3.3 V) as the voltage VDD33 to the semiconductor chip 100 by discharging. The controller 400 controls the external power supply 200, and supplies various control signals to the semiconductor chip 100.

The semiconductor chip 100 includes an IO buffer 110, an internal core circuit 120, the SRAM 130, and a constant-voltage generator 140.

The IO buffer 110 is an interface between the outside and the internal core circuit 120. The IO buffer circuit 110 divides a high-voltage control signal from the controller 400, and supplies the signal to the internal core circuit 120. The IO buffer 110 is a circuit to which a high voltage (the voltage VDD33) is supplied from outside, and hence includes high-withstand-voltage transistors.

The internal core circuit 120 is, e.g., a processor, and controls the interior of the semiconductor chip 100. The internal core circuit 120 operates in accordance with the voltage-divided control signal obtained by the IO buffer circuit 110. The internal core circuit 120 operates at a high speed. Also, the internal core circuit 120 is a circuit to which a low voltage (the internal core voltage VDDC), and hence includes low-withstand-voltage transistors.

The SRAM 130 is a backup SRAM when the main power supply is turned off. In various operations, the SRAM 130 operates by receiving the voltage VDD33 and internal core voltage VDDC from outside. Details of the SRAM 130 will be described later.

The constant-voltage generator 140 generates a constant voltage and supplies the voltage to the SRAM 130. The constant-voltage generator 140 is, e.g., a BGR (Band Gap Reference). The BGR generates a constant voltage having a small temperature characteristic based on, e.g., the voltage from the external power supply 200.

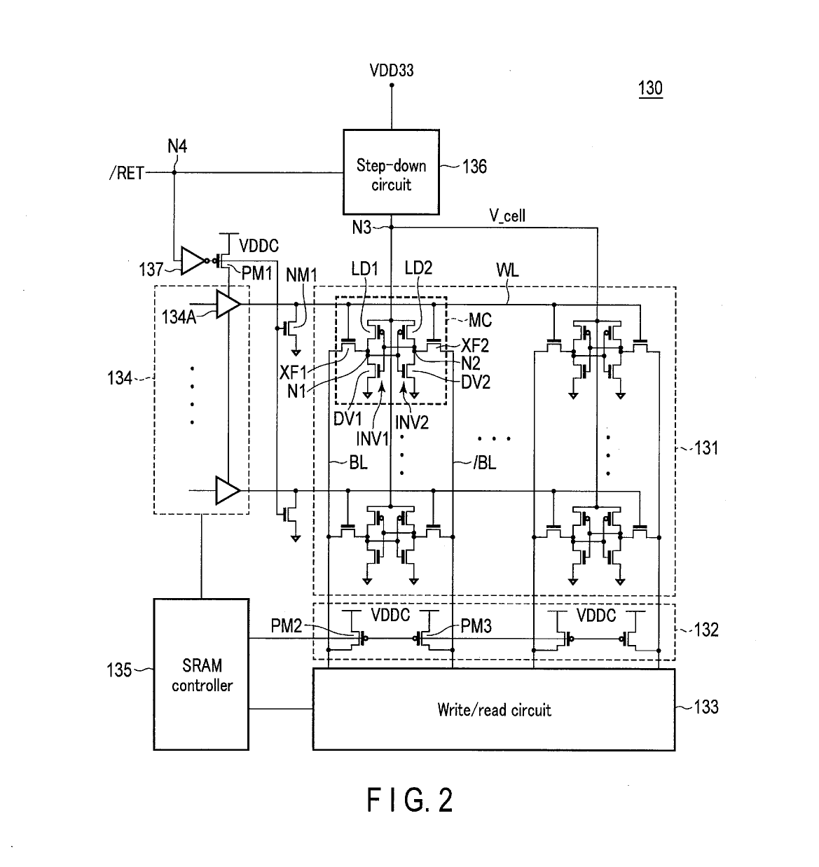

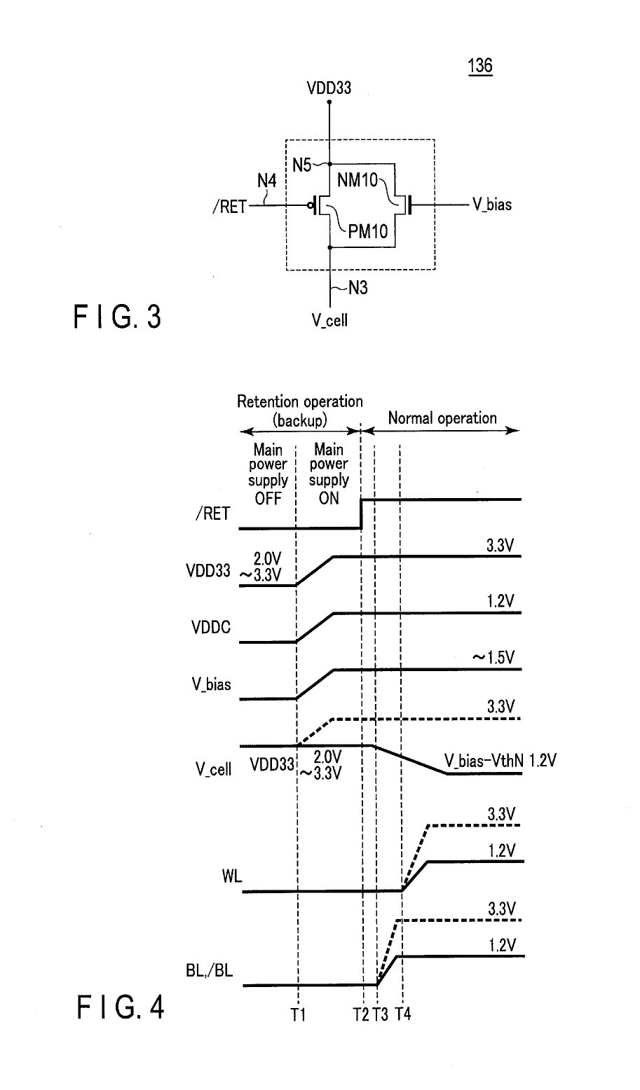

FIG. 2 is a block diagram showing the arrangement of the SRAM 130 according to the first embodiment. FIG. 3 is a circuit diagram showing the arrangement of a step-down circuit 136 according to the first embodiment.

As shown in FIG. 2, the SRAM 130 includes the memory cell array 131, the peripheral circuits, the step-down circuit 136, and an inverter 137. Note that in this embodiment, the peripheral circuits are positioned in the periphery of the memory cell array 131, and mainly supply voltages to word lines WL and pairs of bit line BL and /BL. The peripheral circuits include a precharge circuit 132, write/read circuit 133, row decoder 134, and SRAM controller 135.

The memory cell array 131 includes a plurality of static memory cells MC. The plurality of memory cells MC are arranged in a matrix. The memory cell array 131 also includes a plurality of word lines WL and a plurality of pairs of bit lines BL and /BL. The plurality of word lines WL run in the row direction. The plurality of pairs of bit lines BL and /BL run in the column direction. Each memory cell MC is connected to each word line WL and each pair of bit lines BL and /BL. The word lines WL select rows of the memory cell array 131, and the pairs of bit lines BL and /BL select columns of the memory cell array 131.

The memory cell MC includes a first inverter INV1, a second inverter INV2, and transfer transistors XF1 and XF2.

The first inverter INV1 includes a load PMOS transistor LD1 (to be simply referred to as the PMOS transistor LD1 hereinafter), and a driving NMOS transistor DV1 (to be simply referred to as the NMOS transistor DV1 hereinafter). The PMOS transistor LD1 and NMOS transistor DV1 are connected in series so as to form a current path between a node N3 to which a cell voltage V_cell is supplied and a ground terminal.

The second inverter INV2 includes a load PMOS transistor LD2 (to be simply referred to as the PMOS transistor LD2 hereinafter), and a driving NMOS transistor DV2 (to be simply referred to as the NMOS transistor DV2 hereinafter). The PMOS transistor LD2 and NMOS transistor DV2 are connected in series so as to form a current path between the node N3 to which the cell voltage V_cell is supplied and the ground terminal.

More specifically, the source of the PMOS transistor LD1 is connected to the node N3, and the drain thereof is connected to a node N1. The drain of the NMOS transistor DV1 is connected to the node N1, and the source thereof is connected to the ground terminal. The gate of the PMOS transistor LD1 is connected to the gate of the NMOS transistor DV1.

The source of the PMOS transistor LD2 is connected to the node N3, and the drain thereof is connected to a node N2. The drain of the NMOS transistor DV2 is connected to the node N2, and the source thereof is connected to the ground terminal. The gate of the PMOS transistor LD2 is connected to the gate of the NMOS transistor DV2.

The gates of the PMOS transistor LD1 and NMOS transistor DV1 are connected to the node N2. The gates of the PMOS transistor LD2 and NMOS transistor DV2 are connected to the node N1. In other words, the first and second inverters INV1 and INV2 are cross-coupled. That is, the output terminal (node N1) of the first inverter INV1 is connected to the input terminal of the second inverter INV2 (the gates of the PMOS transistor LD2 and NMOS transistor DV2). Also, the output terminal (node N2) of the second inverter INV2 is connected to the input terminal of the first inverter INV1 (the gates of the PMOS transistor LD1 and NMOS transistor DV1).

The node N1 is connected to the bit line BL via the transfer transistor XF1 formed by an NMOS transistor. That is, the source of the transfer transistor XF1 is connected to the node N1, and the drain thereof is connected to the bit line BL. The gate of the transfer transistor XF1 is connected to the word line WL.

The node N2 is connected to the bit line /BL via the transfer transistor XF2 formed by an NMOS transistor. That is, the source of the transfer transistor XF2 is connected to the node N2, and the drain thereof is connected to the bit line /BL. The gate of the transfer transistor XF2 is connected to the word line WL.

The memory cell MC is thus formed.

The write/read circuit 133 is connected to the pairs of bit lines BL and /BL. The write/read circuit 133 includes a column decoder (not shown), decodes a column address signal from the SRAM controller 135, and selects a corresponding pair of bit lines BL and /BL. Then, the write/read circuit 133 performs data write and read on the selected column. That is, the write/read circuit 133 writes externally input data as write data to the memory cell array 131. Also, the write/read circuit 133 reads data from the memory cell array 131, and outputs the readout data as output data to the outside.

The precharge circuit 132 includes PMOS transistors PM2 and PM3. The source of the PMOS transistor PM2 is connected to the internal core power terminal, and the drain thereof is connected to the bit line BL. The source of the PMOS transistor PM3 is connected to the internal core power terminal, and the drain thereof is connected to the bit line /BL. The SRAM controller 135 inputs a precharge signal to the gates of the PMOS transistors PM2 and PM3.

The precharge circuit 132 precharges the pair of bit lines BL and /BL before executing read and write operations. For example, the precharge circuit 132 executes the precharge operation based on a precharge signal from the SRAM controller 135. That is, the precharge circuit 132 precharges the pair of bit lines BL and /BL when the precharge signal is activated, and cancels the precharge when the precharge signal is deactivated.

The row decoder 134 includes a plurality of word-line drivers 134A. Each word-line driver 134A is connected to each word line WL. Each word-line driver 134A is also connected to the internal core power terminal via the PMOS transistor PM1. The row decoder 134 decodes a row address signal from the SRAM controller 135, and selects a corresponding word line WL. That is, the word-line driver 134A supplies the internal core voltage VDDC from the internal core power terminal to the word line WL based on the row address signal from the SRAM controller 135. Furthermore, each word line WL is connected to the ground terminal via the NMOS transistor NM1.

The SRAM controller 135 supplies various signals to the precharge circuit 132, write/read circuit 133, and row decoder 134, and controls them.

The input terminal of the inverter 137 is connected to a node N4. A retention signal /RET is input to the node N4. The retention signal /RET is a high-voltage signal generated based on the voltage VDD33 from the external power supply 200. The inverter 137 receives the voltage VDD33 and ground voltage, inverts the retention signal /RET, and supplies the inverted signal to the gates of the PMOS transistor PM1 and NMOS transistor NM1.

In a retention operation, the step-down circuit 136 directly outputs the voltage VDD33, without stepping down the voltage, as the cell voltage V_cell to the memory cell array 131. On the other hand, in a normal operation, the step-down circuit 136 steps down the voltage VDD33, and outputs the stepped-down voltage as the cell voltage V_cell to the memory cell array 131.

More specifically, as shown in FIG. 3, the step-down circuit 136 includes a PMOS transistor PM10 and NMOS transistor NM10. The PMOS transistor PM10 and NMOS transistor NM10 are connected in parallel. More specifically, the source of the PMOS transistor PM10 is connected to the external power terminal via a node N5, and the drain thereof is connected to the node N3. The gate of the PMOS transistor PM10 is connected to the node N4, and receives the retention signal /RET. The drain of the NMOS transistor NM10 is connected to the external power terminal via the node N5, and the source thereof is connected to the node N3. A voltage V_bias is supplied to the gate of the NMOS transistor NM10. The voltage V_bias is, e.g., the constant voltage generated by the constant-voltage generator 140.

In various operations, a high voltage is supplied as the voltage VDD33 from the external power terminal to the memory cell array 131, step-down circuit 136, and inverter 137. Therefore, the memory cell array 131, step-down circuit 136, and inverter 137 are formed by high-withstand-voltage transistors. On the other hand, in various operations, a low voltage is supplied as the internal core voltage VDDC from the internal core power terminal to the peripheral circuits (the precharge circuit 132, write/read circuit 133, row decoder 134, and SRAM controller 135). Accordingly, the peripheral circuits are formed by low-withstand-voltage transistors compared to the memory cell array 131, step-down circuit 136, and inverter 137.

Furthermore, in various operations, a high voltage is supplied as the voltage VDD33 to the NMOS transistor NM1 and PMOS transistor PM1 via the inverter 137. Therefore, the NMOS transistor NM1 and PMOS transistor PM1 are formed by high-withstand-voltage transistors like the memory cell array 131, step-down circuit 136, and inverter 137.

### [Operations of First Embodiment]

Next, the operations of the first embodiment will be explained with reference to FIG. 4.

FIG. 4 is a timing chart showing the retention operation (backup) and normal operation according to the first embodiment. Note that the broken lines indicate a comparative example in FIG. 4.

As shown in FIG. 4, when the main power supply is turned off in the retention operation, the battery 300 supplies a backup voltage of, e.g., about 2.0 to 3.3 V as the voltage VDD33. Also, the controller 400 supplies an L (Low)-level retention signal /RET, and the constant-voltage generator 140 supplies 0 V as the voltage V_bias. Consequently, the PMOS transistor PM10 is turned on, and the NMOS transistor NM10 is turned off. In this state, an electric current flows from the source (N5) to the drain (N3) of the PMOS transistor PM10. Since the absolute value (the voltage difference between the gate and the source) of a voltage VGS is much larger than the absolute value of Vthp (<0, Vthp is the threshold voltage of the PMOS transistor PM10), a sufficiently high voltage is transferred from the source to the drain. As a consequence, the step-down circuit 136 (the PMOS transistor PM10) directly transfers the voltage VDD33, so the cell voltage V_cell becomes the same level as that of the voltage VDD33. Accordingly, the memory cell MC can retain data.

On the other hand, the inverter 137 outputs an H (High)-level (e.g., 3.3 V) voltage by inverting the L-level retention signal /RET. This voltage is a voltage which turns on the NMOS transistor NM1. Accordingly, the PMOS transistor PM1 is turned off, and the NMOS transistor NM1 is turned on. Consequently, the word line WL is set at the ground voltage (e.g., 0 V). In addition, the write/read circuit 133 sets the pair of bit lines BL and /BL at 0 V.

Then, when the main power supply is turned on in the retention operation at time T1, the external power supply 200 supplies, e.g., 3.3 V as the voltage VDD33. Also, the internal core circuit 120 supplies, e.g., 1.2 V as the internal core voltage VDDC, and the constant-voltage generator 140 supplies, e.g., 1.5 V as the voltage V_bias.

After that, when the normal operation is started at time T2, the controller 400 supplies the H-level retention signal /RET. In addition, a voltage of, e.g., 1.5 V is supplied as the voltage V_bias as described above. Accordingly, the PMOS transistor PM10 is turned off, and the NMOS transistor NM10 is turned on. In this state, an electric current flows from the drain (N5) to the source (N3) of the NMOS transistor NM10. The voltage VGS is transferred to such an extent that it becomes Vthn (>0, Vthn is the threshold voltage of the NMOS transistor NM10). That is, Vthn=VGS=V_bias−V_cell holds. Therefore, a voltage [V_bias−Vthn] is transferred as the cell voltage V_cell. The voltage [V_bias−Vthn] is, e.g., about 1.2 V. Thus, the step-down circuit 136 (the NMOS transistor NM10) steps down the voltage VDD33 and transfers it.

On the other hand, the inverter 137 outputs an L-level voltage by inverting the H-level retention signal /RET. Accordingly, the PMOS transistor PM1 is turned on, and the NMOS transistor NM1 is turned off. As a consequence, an internal core voltage VDDC of 1.2 V is supplied to the word-line driver 134A.

After that, a write operation or read operation is performed in the normal operation. Note that the word line WL shown in FIG. 4 indicates a selected word line WL.

The read operation is performed as follows.

First, at time T3, the SRAM controller 135 supplies the L-level voltage to the gates of the PMOS transistors PM2 and PM3. Therefore, the PMOS transistors PM2 and PM3 are turned on. Consequently, an internal core voltage VDDC of 1.2 V is transferred to the pair of bit lines BL and /BL, so the pair of bit lines BL and /BL are precharged to a voltage of about 1.2 V.

Then, at time T4, the word-line driver 134A applies a voltage of about 1.2 V to the selected word line WL. When the selected word line WL rises, the transfer transistors XF1 and XF2 having the gates connected to the selected word line WL are turned on. Accordingly, the pair of bit lines BL and /BL operate in accordance with data stored in the memory cell MC. That is, the voltage of the precharged pair of bit lines BL and /BL changes. A sense amplifier (not shown) of the write/read circuit 133 differentially amplifies this level change of the pair of bit lines BL and /BL, and reads the data.

On the other hand, the write operation is performed as follows.

First, at time T3, the SRAM controller 135 supplies the L-level voltage to the gates of the PMOS transistors PM2 and PM3. Accordingly, the PMOS transistors PM2 and PM3 are turned on. As a consequence, an internal core voltage VDDC of 1.2 V is transferred to the pair of bit lines BL and /BL, so the pair of bit lines BL and /BL are precharged to a voltage of about 1.2 V.

Then, at time T4, the word-line driver 134A applies a voltage of about 1.2 V to the selected word line WL. When the selected word line WL rises, the transfer transistors XF1 and XF2 are turned on. Also, a write circuit (not shown) of the write/read circuit 133 sets one of the pair of bit lines BL and /BL at L level in accordance with data to be written. Consequently, the data of the pair of bit lines BL and /BL is stored in the memory cell MC.

The retention operation and normal operation of the first embodiment are performed as described above.

On the other hand, in the comparative example as indicated by the broken lines in FIG. 4, there is no step-down circuit 136, so the voltage VDD33 is supplied to the memory cell MC without being stepped down in the normal operation. In the normal operation, therefore, the cell voltage V_cell becomes a high voltage of about 3.3 V. Accordingly, in the write operation and read operation, the word line WL and the pair of bit lines BL and /BL must be set at a high voltage of about 3.3 V. As a consequence, a high voltage is applied to the peripheral circuits, so the peripheral circuits must be formed by high-withstand-voltage transistors.

By contrast, in the first embodiment, the cell voltage V_cell is a low voltage of about 1.2 V in the normal operation, so the write operation and read operation can be performed even when setting the word line WL and the pair of bit lines BL and /BL at a low voltage of about 1.2 V. Since no high voltage is applied to the peripheral circuits, therefore, the peripheral circuits can be formed by low-withstand-voltage transistors.

### [Effects of First Embodiment]

In the SRAM 130 according to the abovementioned first embodiment, a high voltage (e.g., 3.3 V) is applied as a maximum voltage from the external power supply 200 to the memory cell array 131, and a low voltage (e.g., 1.2 V) is applied as a maximum voltage from the internal core power terminal to the peripheral circuits (the write/read circuit 133, row decoder 134, and SRAM controller 135). That is, no high voltage is applied to the peripheral circuits. Therefore, each transistor of the memory cell array 131 is formed by a high-withstand-voltage transistor, but each transistor of the peripheral circuits can be formed by a low-withstand-voltage transistor. This makes it possible to reduce the circuit area of the peripheral circuits, and reduce the circuit area of the whole SRAM as well.

The aforementioned arrangement can be implemented because the SRAM 130 includes the step-down circuit 136.

If there is no step-down circuit 136, a high voltage (e.g., 3.3 V) is applied as the voltage VDD33 from the external power supply 200 to the memory cell array 131 in the normal operation. That is, the cell voltage V_cell becomes a high voltage. In this case, in order to perform the write operation and read operation, a high voltage must be applied from the peripheral circuits to the memory cell array 131, i.e., the pair of bit lines BL and /BL and the word line WL. Consequently, a high voltage is applied to the peripheral circuits as well.

In this embodiment, however, the step-down circuit 136 steps down the cell voltage V_cell to a low voltage (e.g., 1.2 V) in the normal operation. Accordingly, the write operation and read operation can be executed even when the voltage to be applied from the peripheral circuits to the pair of bit lines BL and /BL and the word line WL is a low voltage.

### Second Embodiment

A semiconductor memory device according to the second embodiment will be explained.

In the second embodiment, an NMOS transistor NM10 in a step-down circuit 136 and NMOS transistors DV1 and DV2 in a memory cell MC have the same threshold voltage, in addition to the arrangement of the first embodiment. This makes it possible to increase the disturb margin of data (improve the data retention characteristic) and improve the write characteristic. The second embodiment will be explained in detail below.

### [Arrangement of Second Embodiment]

The arrangement of the semiconductor memory device according to the second embodiment will be explained below.

In the second embodiment, the NMOS transistor NM10 in the step-down circuit 136 and the NMOS transistors DV1 and DV2 in the memory cell MC have the same arrangement. More specifically, the NMOS transistor NM10 and NMOS transistors DV1 and DV2 have the same transistor size, layout, film thickness, material, and the like.

The transistor size indicates the gate length and gate width. The layout indicates the well space, source/drain diffusion layer, and the like.

Accordingly, a threshold voltage Vthn of the NMOS transistor NM10 becomes the same as the threshold voltage of the NMOS transistors DV1 and DV2. In other words, the threshold voltage of the NMOS transistors DV1 and DV2 is reflected on the threshold voltage Vthn of the NMOS transistor NM10.

The NMOS transistor NM10 and NMOS transistors DV1 and DV2 are formed by the same process.

In the second embodiment, a β ratio is about 1.0. The β ratio is the ratio of the transistor size of the NMOS transistors DV1 and DV2 to that of NMOS transistors XF1 and XF2 in the memory cell MC.

### [Effects of Second Embodiment]

When the threshold voltage of the NMOS transistors DV1 and DV2 in the memory cell MC decreases in a normal operation, the data disturb margin decreases, and the write characteristic improves. That is, increasing the data disturb margin and improving the write characteristic cannot be achieved at the same time, i.e., they are contradictory. Note that the decrease in data disturb margin indicates the easiness of data inversion, and the increase in data disturb margin indicates the difficulty of data inversion.

In the second embodiment, the NMOS transistors DV1 and DV2 and the NMOS transistor NM10 have the same threshold voltage. In other words, the threshold voltage of the NMOS transistors DV1 and DV2 is reflected on that of the NMOS transistor NM10.

When the threshold voltage of the NMOS transistors DV1 and DV2 decreases in this arrangement, the threshold voltage Vthn of the NMOS transistor NM10 decreases accordingly. The write characteristic can improve when the threshold voltage of the NMOS transistors DV1 and DV2 decreases. On the other hand, when the threshold voltage Vthn of the NMOS transistor NM10 decreases, a cell voltage V_cell (V_bias−Vthn) increases. When the cell voltage V_cell increases with respect to the selection level of a word line WL in the normal operation, the data disturb margin increases. In this embodiment, the selection level of the word line WL is fixed at an internal core voltage VDDC (1.2 V). Accordingly, the cell voltage V_cell increases, i.e., the data disturb margin can increase when the threshold voltage Vthn of the NMOS transistor NM10 decreases.

As described above, the decrease in data disturb margin caused when the threshold voltage of the NMOS transistors DV1 and DV2 decreases can be suppressed by increasing the cell voltage V_cell. That is, it is possible to increase the data disturb margin and improve the write characteristic at the same time.

Also, the β ratio is normally set to be high in order to stabilize the operation of the memory cell MC by increasing the data disturb margin and improving the write characteristic. More specifically, the β ratio is set at about 1.5 to 2.0.

As described above, the second embodiment can increase the data disturb margin and improve the write characteristic, thereby stabilizing the operation of the memory cell MC. Therefore, the operation of the memory cell MC can be stabilized even when the β ratio is decreased. More specifically, the β ratio can be set at about 1.0. That is, it is possible to equalize the transistor size of the NMOS transistors DV1 and DV2 and that of the transfer transistors XF1 and XF2. Since the degree of freedom of the layout of these transistors increases, therefore, the area of the memory cell MC can be reduced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising an SRAM,
wherein the SRAM comprises:
a memory cell including a first inverter, a second inverter including an output terminal connected to an input terminal of the first inverter and an input terminal connected to an output terminal of the first inverter, a first transfer transistor including one terminal connected to the output terminal of the first inverter and the input terminal of the second inverter, the other terminal connected to a first bit line, and a gate connected to a word line, and a second transfer transistor including one terminal connected to the output terminal of the second inverter and the input terminal of the first inverter, the other terminal connected to a second bit line, and a gate connected to the word line; and
a peripheral circuit configured to supply various voltages to the word line, the first bit line, and the second bit line, and
each transistor of the memory cell is formed by a high-withstand-voltage transistor, and each transistor of the peripheral circuit is formed by a low-withstand-voltage transistor having a withstand voltage lower than that of the high-withstand-voltage transistor.

2. The device of claim 1, wherein a first voltage is supplied from a first power terminal to the memory cell, and a second voltage lower than the first voltage is supplied from a second power terminal to the peripheral circuit.

3. The device of claim 2, wherein the SRAM further comprises a step-down circuit configured to directly supply the first voltage from the first power terminal to the memory cell in a retention operation, and step down the first voltage from the first power terminal and supply the stepped-down voltage to the memory cell in a normal operation.

4. The device of claim 3, wherein the step-down circuit includes a first NMOS transistor configured to form a current path between the first power terminal and the memory cell, and a first PMOS transistor configured to form a current path between the first power terminal and the memory cell, and connected in parallel to the first NMOS transistor.

5. The device of claim 4, wherein
in the retention operation, the first NMOS transistor is turned off, and the first PMOS transistor is turned on, and
in the normal operation, the first NMOS transistor is turned on, and the first PMOS transistor is turned off.

6. The device of claim 2, wherein the memory cell is selected when the second voltage is supplied to the word line in a normal operation.

7. The device of claim 4, wherein
the first inverter includes a second NMOS transistor and a second PMOS transistor connected in series,
the second inverter includes a third NMOS transistor and a third PMOS transistor connected in series, and
the first NMOS transistor has the same threshold voltage as that of the second NMOS transistor and the third NMOS transistor.

8. The device of claim 2, further comprising:
an IO buffer configured to receive the first voltage from the first power terminal; and
an internal core circuit configured to receive the second voltage from the second power terminal, and control an interior of a chip,
wherein each transistor of the IO buffer is formed by the high-withstand-voltage transistor, and each transistor of the internal core circuit is formed by the low-withstand-voltage transistor.

9. The device of claim 1, wherein the peripheral circuit includes:
a precharge circuit configured to precharge the first bit line and the second bit line before executing a write operation and a read operation on the memory cell;
a write/read circuit configured to perform the write operation and the read operation on the memory cell by selecting the first bit line and the second bit line;
a row decoder configured to select the word line in the write operation and the read operation; and
an SRAM controller configured to control the precharge circuit, the write/read circuit, and the row decoder.

10. The device of claim 4, further comprising a constant-voltage generator configured to supply a constant voltage to a gate of the first NMOS transistor.

11. The device of claim 2, further comprising a battery configured to supply the first voltage to the memory cell in a retention operation.

12. The device of claim 4, wherein
the SRAM further comprises an inverter,
the inverter generates a second signal by inverting a first signal supplied to a gate of a first PMOS transistor, and
the second voltage is supplied to the word line based on the second signal.

13. The device of claim 12, wherein the first signal is the first voltage, and the inverter is formed by the high-withstand-voltage transistor.

14. The device of claim 7, wherein the first NMOS transistor has the same transistor size, layout, film thickness, and material as those of the second NMOS transistor and the third NMOS transistor.

15. The device of claim 7, wherein the second NMOS transistor and the third NMOS transistor have the same transistor size as that of the first transfer transistor and the second transfer transistor.

16. The device of claim 4, wherein each of the first NMOS transistor and the first PMOS transistor is formed by the high-withstand-voltage transistor.
